(19) United States
(12) Patent Application Publication
(10) Pub. No.: US 2024/0355974 A1
(43) Pub. Date: Oct. 24, 2024

(54) DISPLAY APPARATUS, AND DISPLAY PANEL AND MANUFACTURING METHOD THEREFOR

(71) Applicants: Yunnan Invensight Optoelectronics Technology Co., Ltd., Yunnan (CN); BOE Technology Group Co., Ltd., Beijing (CN)

(72) Inventors: Zhijian ZHU, Beijing (CN); Pengcheng LU, Beijing (CN); Yunlong LI, Beijing (CN); Dongsheng LI, Beijing (CN); Dacheng ZHANG, Beijing (CN); Shengji YANG, Beijing (CN); Kuanta YANG, Beijing (CN); Xiaochuan CHEN, Beijing (CN)

(73) Assignees: Yunnan Invensight Optoelectronics Technology Co., Ltd., Yunnan (CN); BOE Technology Group Co., Ltd., Beijing (CN)

(21) Appl. No.: 18/575,177

(22) PCT Filed: Oct. 29, 2021
(86) PCT No.: PCT/CN2021/127483

§ 371 Date: Dec. 28, 2023

(51) Int. Cl. H01L 33/58; H01L 25/075; H01L 25/16; H01L 27/15; H01L 33/62

(52) U.S. Cl. CPC H01L 33/58; H01L 25/0753; H01L 25/167; H01L 27/156; H01L 33/62; H01L 2933/0058

(57) ABSTRACT

A display apparatus, and a display panel and a manufacturing method therefor. The display panel includes a driving backplane and a plurality of light-emitting modules on one side of the driving backplane, the driving backplane is provided with a pixel region including a central region and n offset regions, and n is a positive integer. Each light-emitting module includes a plurality of light-emitting units, and each light-emitting unit includes a corresponding light-emitting device and a corresponding converging lens; in any light-emitting unit of an offset region, the center of a light-emitting device is offset to the side of the center of a converging lens away from the central region, so as to obtain an offset amount and an offset direction; the offset amounts of light-emitting units of a same offset region are the same; the offset directions of light-emitting units of a same light-emitting module are the same.

### TECHNICAL FIELD

The present disclosure relates to the field of display technology, and in particular, to a display apparatus, a display panel, and a manufacturing method therefor.

### BACKGROUND

Virtual reality (VR) devices and augmented reality (AR) devices using near-eye display technology have been applied to gaming, medical and other fields. The optical system is used to create an image within the focus range of the eye based on the display content of the display panel. However, the uniformity of images displayed by some near-eye display devices still needs to be improved.

It should be noted that the information disclosed in the above background technology section is intended only to enhance the understanding of the background of the present disclosure, and thus may include information that does not constitute prior art known to those of ordinary skill in the art.

### SUMMARY

The present disclosure provides a display apparatus, a display panel, and a manufacturing method therefor.

According to an aspect of the present disclosure, there is provided a display panel, including:
a driving backplane, having a pixel region, wherein the pixel region includes a central region and n offset regions sequentially surrounding outside the central region, n is a positive integer;
a plurality of light-emitting modules, provided on a side of the driving backplane and distributed in the central region and the offset regions, wherein one of the light-emitting modules includes a plurality of light-emitting units, and one of the light-emitting units includes a light-emitting device and a converging lens distributed along a direction away from the driving backplane;
in any of the light-emitting units in the offset region, a center of an orthographic projection of the light-emitting device on the driving backplane is located on a side of a center of an orthographic projection of the converging lens on the driving backplane away from the central region, and a distance between the center of the orthographic projection of the light-emitting device on the driving backplane and the center of the orthographic projection of the converging lens on the driving backplane is an offset amount of the light-emitting unit; and an extension direction of a connecting line between the center of the orthographic projection of the light-emitting device on the driving backplane and the center of the orthographic projection of the converging lens on the driving backplane is an offset direction of the light-emitting device;
offset amounts of the light-emitting units in an identical offset region are identical; and offset directions of the light-emitting units in an identical light-emitting module are identical; and
an offset amount of the light-emitting unit in the central region is zero; offset amounts of the light-emitting units in any of the offset regions are greater than the offset amount of the light-emitting unit in the central region, and offset amounts of the light-emitting units in each of the offset regions increase toward a direction away from the central region.

In an example embodiment of the present disclosure, the light-emitting units are distributed in an array along a row direction and a column direction;
components of the offset amounts of the light-emitting units in each of the offset regions in the row direction gradually increase toward two sides of the central region along the row direction;
components of the offset amounts of the light-emitting units in each of the offset regions in the column direction gradually increase toward two sides of the central region along the column direction.

In an example embodiment of the present disclosure, the offset region includes a plurality of sub-regions distributed around the central region; the light-emitting modules are distributed in each of the sub-regions;
in an identical offset region, a first central axis of the pixel region passes through at least one of the sub-regions, and a second central axis of the pixel region passes through at least one of the sub-regions; the first central axis is a central axis extending along the row direction, and the second central axis is a central axis extending along the column direction;
a component of the offset amount of the light-emitting unit in the sub-region through which the first central axis passes in the column direction is zero; and a component of the offset amount of the light-emitting unit in the sub-region through which the second central axis passes in the row direction is zero.

In an example embodiment of the present disclosure, the light-emitting unit further includes:
a filter part, provided between the light-emitting device and the converging lens;
colors of the filter parts of at least two different light-emitting units of the identical light-emitting module are different.

In an example embodiment of the present disclosure, a center of an orthographic projection of the filter part on the driving backplane coincides with the center of the orthographic projection of the converging lens on the driving backplane.

In an example embodiment of the present disclosure, a component of the offset amount of any of the light-emitting units in the row direction satisfies the following relational expression:

$$0 \leq Δ {S}_{x} \leq ( {P}_{x} - {D}_{x} ) / 2 ;$$

wherein, ΔSₓ is the component of the offset amount of any of the light-emitting units in the row direction;
Pₓ is a length of a filter part of the light-emitting unit corresponding to ΔSₓ in the row direction;
Dₓ is a length of the light-emitting device of the light-emitting unit corresponding to ΔSₓ in the row direction.

In an example embodiment of the present disclosure, a component of the offset amount of any of the light-emitting units in the row direction satisfies the following relational expression:

$$0 \leq Δ {S}_{y} \leq ( {P}_{y} - {D}_{y} ) / 2 ;$$

wherein, ΔS_{y} is the component of the offset amount of any of the light-emitting units in the column direction;
P_{y} is a length of a filter part of the light-emitting unit corresponding to ΔS_{y} in the column direction;
D_{y} is a length of the light-emitting device of the light-emitting unit corresponding to ΔS_{y} in the column direction.

In an example embodiment of the present disclosure, the offset amount of any one of the light-emitting units satisfies the following relational expression:

$$Δ S = {( {( 2 x Δ {S}_{x max} / W )}^{2} + {( 2 y Δ {S}_{y max} / L )}^{2} )}^{\frac{1}{2}} ;$$

wherein, ΔS is the offset amount of the light-emitting unit;
x is a distance in the row direction between a center of the sub-region where the light-emitting unit is located and a center of the central region;
y is the distance in the column direction between the center of the sub-region where the light-emitting unit is located and the center of the central region;
ΔSₓₘₐₓ is a component of an offset amount of the light-emitting unit in the offset region farthest from the central region in the row direction;
ΔS_{ymax} is a component of an offset amount of the light-emitting unit in the offset region farthest from the central region in the column direction;
W is a length of the pixel region in the row direction;
L is the length of the pixel region in the column direction.

In an example embodiment of the present disclosure, each of the offset regions is divided into m sections sequentially distributed toward a direction away from the central region, and each of the sections includes a plurality of the offset regions; m is a positive integer;
in any of the sections, the offset amounts of the light-emitting units in each of the offset regions linearly increase with increase of a distance between the offset region and the central region, and a growth rate of the offset amount is that of the section;
growth rates of at least two of the sections are different.

In an example embodiment of the present disclosure, the sections include a first section, a second section and a third section sequentially distributed toward a direction away from the central region;
a growth rate of the second section is greater than that of the first section, and a growth rate of the third section is less than that of the first section.

In an example embodiment of the present disclosure, in an identical offset region, an included angle between a direction with a maximum luminous intensity of the light-emitting unit in the sub-region passing through the first central axis and a direction perpendicular to the driving backplane is a first included angle; and an included angle between a direction with the maximum luminous intensity of the light-emitting unit in the sub-region passing through the second central axis and a direction perpendicular to the driving backplane is a second included angle;
the first included angle and the second included angle satisfy the following relational expression:

$$α = β W / L ;$$

wherein, α is the first included angle, and β is the second included angle.

In an example embodiment of the present disclosure, the converging lens is a spherical cap structure protruding away from the driving backplane.

In an example embodiment of the present disclosure, the display panel further includes:
an encapsulation layer, covering each of the light-emitting modules; wherein the filter part is provided on a side of the encapsulation layer away from the driving backplane.

In an example embodiment of the present disclosure, in an identical offset region, at least two of the light-emitting modules are distributed along the row direction; and at least two of the light-emitting modules are distributed along the column direction.

In an example embodiment of the present disclosure, the number of light-emitting units in a (k+1)-th offset region in a direction away from the central region is greater than the number of light-emitting units in the k-th offset region, k is a positive integer less than n.

In an example embodiment of the present disclosure, at least one straight line passing through a center of the central region exists, the number of light-emitting units passing through a (k+1)-th offset region in a direction away from the central region is not less than the number of light-emitting units passing through the k-th offset region, k is a positive integer less than n.

In an example embodiment of the present disclosure, in an identical light-emitting unit, the orthographic projection of the light-emitting device on the driving backplane at least partially coincides with the orthographic projection of the converging lens on the driving backplane.

In an example embodiment of the present disclosure, a gap exists between two adjacent converging lenses;
in two adjacent light-emitting units in the k-th offset region in the direction away from the central region, an orthographic projection of the gap between two adjacent converging lenses on the driving backplane is at least partially located within an orthographic projection of a gap between the two adjacent light-emitting devices on the driving backplane;
in two adjacent light-emitting units in the (k+1)-th offset region in the direction away from the central region, an orthographic projection of the gap between two adjacent converging lenses on the driving backplane is completely located outside the orthographic projection of the gap between the two adjacent light-emitting devices on the driving backplane;
k is a positive integer less than n.

In an example embodiment of the present disclosure, a width of the filter part in the (k+1)-th offset region in a direction away from the central region is greater than a width of the filter part with an identical color in the k-th offset region as in the (k+1)-th offset region;
k is a positive integer less than n.

According to an aspect of the present disclosure, there is provided a method of manufacturing a display panel, including:
forming a driving backplane having a pixel region, wherein the pixel region includes a central region and n offset regions sequentially surrounding outside the central region, n is a positive integer;
forming a plurality of light-emitting devices distributed in an array in the central region and the offset regions on a side of the driving backplane;
forming converging lenses corresponding to the light emitting devices one by one on a side of the light-emitting device away from the driving backplane, wherein the converging lens is used for converging light emitted by the light-emitting devices within a specified angle;
dividing each of the light-emitting units into a plurality of light-emitting modules, wherein one of the light-emitting modules includes a plurality of light-emitting units, and one of the light-emitting units includes a light-emitting device and a corresponding converging lens;
wherein in any of the light-emitting units in the offset region, a center of an orthographic projection of the light-emitting device on the driving backplane is located on a side of a center of an orthographic projection of the converging lens on the driving backplane away from the central region, and a distance between the center of the orthographic projection of the light-emitting device on the driving backplane and the center of the orthographic projection of the converging lens on the driving backplane is an offset amount of the light-emitting unit; and an extension direction of a connecting line between the center of the orthographic projection of the light-emitting device on the driving backplane and the center of the orthographic projection of the converging lens on the driving backplane is an offset direction of the light-emitting device;
offset amounts of the light-emitting units in an identical offset region are identical; and offset directions of the light-emitting units in an identical light-emitting module are identical; and
an offset amount of the light-emitting unit in the central region is zero; offset amounts of the light-emitting units in any of the offset regions are greater than the offset amount of the light-emitting unit in the central region, and offset amounts of the light-emitting units in each of the offset regions increase toward a direction away from the central region.

According to an aspect of the present disclosure, there is provided a display apparatus, including any of the display panels described above.

It should be understood that the above general description and the later detailed descriptions are exemplary and explanatory only and do not limit the present disclosure.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure. The drawings in the following description are only some embodiments of the present disclosure. For those of ordinary skill in the art, other drawings can be obtained based on these drawings without exerting creative efforts.

FIG. 1 is a schematic cross-sectional view of a display panel according to an embodiment of the present disclosure.

FIG. 2 is a schematic distribution diagram of the central region and the offset region of the display panel according to an embodiment of the present disclosure.

FIG. 3 is a schematic distribution diagram of light-emitting modules of the display panel according to an embodiment of the present disclosure.

FIG. 4 is a schematic diagram of a light-emitting unit of a display panel according to an embodiment of the present disclosure.

FIG. 5 is a schematic distribution diagram of chief ray angles in the column direction of the display panel in an embodiment of the present disclosure.

FIG. 6 is a schematic diagram showing the distribution of chief ray angles in the row direction of the display panel in an embodiment of the present disclosure.

FIG. 7 is a schematic diagram of the relationship between chief ray angles and half-image height of the display panel in an embodiment of the present disclosure.

### DETAILED DESCRIPTION

The example embodiments will now be described more fully with reference to the accompanying drawings. However, the example embodiments can be implemented in a variety of forms and should not be construed as being limited to the examples set forth herein; rather, the provision of these embodiments makes the present disclosure more comprehensive and complete and communicates the ideas of the example embodiments to those skilled in the art in a comprehensive manner. The same reference numerals in the drawings indicate the same or similar structures, and thus their detailed description will be omitted. In addition, the accompanying drawings are only schematic illustrations of the present disclosure and are not necessarily drawn to scale.

The terms “a”, “an”, “the”, “said” and “at least one” are used to indicate the presence of one or more elements/components/etc.; the terms “including” and “having” are used to indicate an open-ended inclusion and refer to the presence of additional elements/components/etc. in addition to the listed elements/components/etc.; the terms “first”, “second”, and “third” etc. are used as markers only and are not limitations on the number of objects.

The positional relationship between the A feature (light-emitting module, light-emitting unit, light-emitting device, filter part, etc.) besides the driving backplane and the central region and offset region described herein refers to the positional relationship of the orthographic projection of the A feature on the driving backplane and the central region and the offset region. For example, the light-emitting module being located in the offset region means that the orthographic projection of the light-emitting module on the driving backplane is located in the offset region.

The row direction and column direction are only two mutually perpendicular directions. In the embodiments shown in the drawings of the present disclosure, the row direction may be a horizontal direction and the column direction may be a vertical direction. However, the row direction is not limited to the transverse direction, and the column direction is not limited to the longitudinal direction. Those skilled in the art can know that the actual orientation of the row direction and column direction may change if the display panel is rotated. Therefore, the embodiments herein do not constitute a limitation on the actual orientations of the row and column directions.

In related technologies, near-eye display devices such as virtual reality devices and augmented reality devices may include a display panel and an optical path component. The optical path component is located on the light-emitting side of the display panel and is used to adjust the light path of the display panel, and form an image that can be viewed by the user in a designated space. Due to the low efficiency of the optical path component and high light loss, the brightness of the near-eye display device is affected. Especially when used outdoors, if the brightness of the near-eye display device is low, it is not conducive to users viewing images. The light path component is located on the light-emitting side of the display panel and is used to adjust the light path of the display panel, and form an image that can be viewed by the user in a designated space. The display panel may include a plurality of light-emitting devices and a plurality of lenses. Each lens is located on the light-emitting side of the light-emitting device and is arranged in one-to-one correspondence with each light-emitting device. The light emitted by the light-emitting device can be converged to a specified range through the lens. By preventing the light from being too diffuse, the brightness of the display panel can be increased through the lens.

However, the inventor found that since the image viewed by the user is an image formed by adjusting the light path through the light path component, the user does not directly see the display panel. However, the brightness and luminous range of the picture presented after the light path system adjusts the light of the display panel is not consistent with the picture directly displayed by the display panel. The luminous range required by the near-eye display device is greater than the actual luminous range of the display panel, resulting in the low brightness uniformity of the picture presented by the near-eye display device.

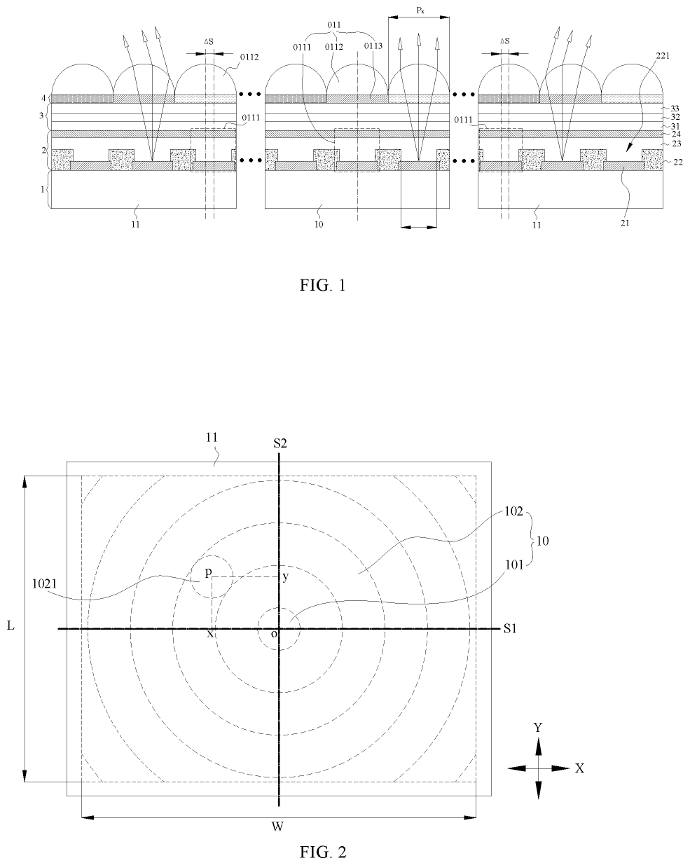

The embodiment of the present disclosure provides a display panel, as shown in FIGS. 1-3. The display panel of the present disclosure may include a driving backplane 1 and a plurality of light-emitting modules 01, wherein:
a driving backplane 1 has a pixel region 10, wherein the pixel region 10 includes a central region 101 and n offset regions 102 sequentially surrounding outside the central region 101, n is a positive integer;
a plurality of light-emitting modules 01 are provided on a side of the driving backplane 1 and distributed in the central region 101 and the offset regions 102, wherein one of the light-emitting modules 01 includes a plurality of light-emitting units 011, and one of the light-emitting units 011 includes a light-emitting device 0111 and a converging lens 0112 distributed along a direction away from the driving backplane 1;
in any of the light-emitting units 011 in the offset region 102, a center of an orthographic projection of the light-emitting device 0111 on the driving backplane 1 is located on a side of a center of an orthographic projection of the converging lens 0112 on the driving backplane 1 away from the central region 101, and a distance between the center of the orthographic projection of the light-emitting device 0111 on the driving backplane 1 and the center of the orthographic projection of the converging lens 0112 on the driving backplane 1 is an offset amount of the light-emitting unit 011; and an extension direction of a connecting line between the center of the orthographic projection of the light-emitting device 0111 on the driving backplane 1 and the center of the orthographic projection of the converging lens 0112 on the driving backplane 1 is an offset direction of the light-emitting device 0111;
offset amounts of the light-emitting units 011 in an identical offset region 102 are identical; and offset directions of the light-emitting units 011 in an identical light-emitting module 01 are identical; and
an offset amount of the light-emitting unit 011 in the central region 101 is zero; offset amounts of the light-emitting units 011 in any of the offset regions 102 are greater than the offset amount of the light-emitting unit 011 in the central region 101, and offset amounts of the light-emitting units 011 in each of the offset regions 102 increase toward a direction away from the central region 101.

In the display panel of the embodiment of the present disclosure, the light-emitting angle of the light-emitting unit 011 can be adjusted by shifting the positions of the light-emitting device 0111 and converging lens 0112 in the same light-emitting unit 011, so as to match with the optical path components in the near-eye display devices such as virtual devices or augmented devices, to improve the uniformity of the light emission of the near-eye display device and improve the uniformity of the pictures actually seen by the user.

Specifically, in order to facilitate the description of technical effects, the included angle between the direction with the maximum luminous intensity of any light-emitting unit 011 and the direction perpendicular to the screen can be defined as the chief ray angle.

The chief ray angles of the light-emitting units 011 in the same offset region 102 are the same, and the chief ray angles of the light-emitting units 011 in different offset regions 102 increase in the direction away from the central region 101, thereby increasing the luminous range of the display pane, so as to match the luminous range of the display panel with the optical path component, and improve the uniformity of the brightness of the picture presented by the near-eye display device.

The structure of the display panel of the present disclosure to realize the display function is described in detail below.

As shown in FIGS. 1 to 3, the driving backplane 1 of the display panel may include a pixel region 10 and a peripheral region 11. The peripheral region 11 is located outside the pixel region 10. The peripheral region 11 may be an annular region provided around the pixel region 10. The driving backplane 1 is used to form a driving circuit that drives each light-emitting device 0111 to emit light. The driving circuit may include a pixel circuit and a peripheral circuit.

The number of pixel circuits and light-emitting devices 0111 can be plural, and the pixel circuit is located in the pixel region 10. The pixel circuit can be a pixel circuit such as 2T1C, 4T2C, 6T1C or 7T1C, as long as it can drive the light-emitting device 0111 to emit light. There is no special restriction on its structure herein. The number of pixel circuits can be the same as the number of light-emitting devices 0111, and they are connected to the light-emitting devices 0111 in one-to-one correspondence, so as to control each light-emitting device 0111 to emit light respectively. In the embodiment, nTmC means that a pixel circuit includes n transistors (indicated by the letter “T”) and m capacitors (indicated by the letter “C”). The same pixel circuit can also drive a plurality of light-emitting devices 0111.

The peripheral circuit is located in the peripheral region 11 and connected to the pixel circuit. The peripheral circuit may include at least one of a light-emitting control circuit, a gate driving circuit, a source driving circuit, and a power supply circuit. It may also include other circuits, as long as the light-emitting device 0111 can be driven to emit light through the pixel circuit.

In some embodiments of the present disclosure, the driving backplane 1 may include a substrate and at least one wiring layer provided on the substrate, wherein the substrate may be a silicon substrate, and the driving circuit may be formed on the silicon substrate through a semiconductor process. For example, both the pixel circuit and the peripheral circuit may include a plurality of transistors, and a well region may be formed in the silicon substrate through a doping process, and the well region has two doped regions spaced apart. At the same time, taking one well region as an example, a gate is provided on one side of the driving backplane 1, that is, the orthographic projection of the gate on the substrate is located between the two doped regions. At least one wiring layer is connected to the doped regions, and one wiring layer may include a source electrode and a drain electrode connected to two doped regions of the same well region. The transistors are connected through each wiring layer to form a driving circuit. The specific connection lines and wiring patterns depend on the circuit structure, which is not specifically limited here.

The wiring layer can be covered with a flat layer, the material of which can be silicon oxide, silicon oxynitride or silicon nitride, and formed layer by layer through multiple deposition and polishing processes. The flat layer can be formed by a plurality of laminated insulating film layers.

As shown in FIGS. 1 to 3, a light-emitting functional layer 2 can be provided on the driving backplane 1. The light-emitting functional layer 2 can include a plurality of light-emitting devices 0111. The light-emitting devices 0111 are distributed in an array on one side of the driving backplane 1. For example, each light-emitting device 0111 is provided on the surface of the flat layer away from the substrate. Each light-emitting device 0111 may include a first electrode 21, a second electrode 24, and a light-emitting layer 23 located between the first electrode 21 and the second electrode 24. Both the first electrode 21 and the second electrode 24 may be connected to the wiring layer. At the same time, the peripheral circuit may also include a power supply circuit connected to the second electrode 24, for inputting a power supply signal to the second electrode 24. The peripheral circuit can input a driving signal to the first electrode 21 through the pixel circuit and input a power supply signal to the second electrode 24, to control the light emitting device 0111 to emit light.

In order to achieve color display, each light-emitting device 0111 can emit light of the same color, and cooperate with the color film layer 4 located on the side of the second electrode 24 away from the substrate, to achieve color display. The embodiment of the present disclosure takes this color display scheme as an example for explanation. Each light-emitting device can also emit light independently, and the light-emitting colors of different light-emitting devices 0111 can be different.

In some embodiments of the present disclosure, as shown in FIG. 1, a plurality of light-emitting devices 0111 may be formed by the first electrode layer, the pixel definition layer 22, the light-emitting layer 23 and the second electrode 24.

The first electrode layer is provided on the surface of the flat layer away from the substrate. The first electrode layer may include a plurality of first electrodes 21 distributed at intervals, and the orthographic projection of each first electrode 21 on the substrate is located in the pixel region 10 and is connected to the pixel circuit. One first electrode 21 is connected to one pixel circuit.

As shown in FIG. 1, the pixel definition layer 22 covers the flat layer and exposes each first electrode 21. Specifically, the pixel definition layer 22 is provided with an opening 221 that exposes the first electrode 21. Through the pixel definition layer 22 and its opening 221, the range of each light-emitting device 0111 can be defined, and the light-emitting range of the light-emitting device 0111 is also limited by the opening 221. The boundary of the opening 221 is the boundary of the light-emitting device 0111. The direction in which the luminous intensity of the light-emitting device 0111 is maximum may be a direction perpendicular to the first electrode 21 and passing through the center of the opening 221. The material of the pixel definition layer 22 may be insulating materials such as silicon oxide and silicon nitride, and is not specifically limited here.

As shown in FIG. 1, the light-emitting layer 23 covers the pixel definition layer 22 and the first electrode 21. The region of the light-emitting layer 23 located in an opening 221 and stacked with the first electrode is used to form the light-emitting device 0111. That is, each light-emitting device 0111 may share the same light-emitting layer 23. That is, the parts of the light-emitting layer 23 located in different openings 221 belong to different light-emitting devices 0111. In addition, since each light-emitting device 0111 shares the light-emitting layer 23, different light-emitting devices 0111 emit the same color.

For example, the light-emitting layer 23 may include a plurality of light-emitting sub-layers connected in series in a direction away from the substrate, and at least one light-emitting sub-layer is connected in series with an adjacent light-emitting sub-layer through a charge generation layer. When an electrical signal is applied to the first electrode 21 and the second electrode 24, each light-emitting sub-layer can emit light, and different light-emitting sub-layers can be used to emit light of different colors.

As shown in FIG. 1, the second electrode 24 covers the light-emitting layer 23, and the orthographic projection of the second electrode 24 on the substrate can cover the pixel region 10 and extend into the peripheral region 11. Each light-emitting device 0111 may share the same second electrode 24. When the voltage difference between the second electrode 24 and the first electrode 21 reaches a voltage difference that enables the light-emitting layer 23 to emit light, the light-emitting layer 23 can emit light. Therefore, the light emitting layer 23 may be controlled to emit light by controlling the voltages of the power supply signal input to the second electrode 24 and the driving signal input to the first electrode 21.

As shown in FIG. 1, in some embodiments of the present disclosure, the display panel of the present disclosure may further include an encapsulation layer 3, which may cover each light-emitting device 0111. For example, the encapsulation layer 3 is provided on the side of the second electrode 24 away from the substrate, and is located between the color filter layer 4 and the second electrode 24, to block erosion of external water and oxygen. The encapsulation layer 3 may be a single-layer or multi-layer structure. For example, the encapsulation layer 3 may include a first encapsulation sub-layer 31, a second encapsulation sub-layer 32 and a third encapsulation sub-layer 33 that are sequentially stacked in a direction away from the substrate. The material of the first packaging sub-layer 31 and the second packaging sub-layer 32 can be inorganic insulating materials such as silicon nitride (SiN), aluminum oxide (AL₂O₃), etc. For example, the material of the first packaging sub-layer 31 is silicon nitride, the material of the second packaging sub-layer 32 is aluminum oxide; and the material of the third packaging sub-layer 33 can be organic materials such as Parylene.

As shown in FIG. 1, in order to achieve color display, the display panel may also include a color filter layer 4. The color filter layer 4 may be disposed on the side of the second electrode 24 away from the substrate, and include a plurality of filter parts 0113. Each light-emitting device and each filter part 0113 are arranged opposite to each other one by one in the direction perpendicular to the substrate. That is, the orthographic projection of a filter part 0113 on the flat layer at least partially coincides with a first electrode 21. Each filter part 0113 at least includes filter parts 0113 of three colors, for example, a filter part 0113 that can transmit red light, a filter part 0113 that can transmit green light, and a filter part 0113 that can transmit blue light. After the light emitted by each light-emitting device 0111 is filtered by the filter part 0113, monochromatic light of different colors can be obtained, thereby achieving color display.

The shape of the orthographic projection of the filter part 0113 on the substrate can be larger than the opening 221 of the pixel definition layer 22, and the orthographic projection of each opening 221 on the substrate is located in the orthographic projection of each filter part 0113 on the substrate in one-to-one correspondence.

As shown in FIG. 1, the color filter layer 4 may also include a light-shielding part that separates the filter part 0113. The light-shielding part is opaque and blocks the region between the two light-emitting devices 0111. The filter part 0113 can be spaced apart from the filter part 0113 by directly using a light-shielding material. Alternatively, in some embodiments of the present disclosure, the adjacent filter parts 0113 can be arranged in a stacked manner in the region corresponding to the region between two adjacent light-emitting devices 0111, and the colors of light transmitted by the two light-emitting devices are different, so that the stacked region is opaque.

In addition, in some embodiments of the present disclosure, in order to improve the brightness of the picture, on the basis that the light-emitting layer 23 emits white light, the color filter layer 4 may also include a transparent part. In the direction perpendicular to the substrate, a transparent part may be arranged opposite to a light-emitting unit 011, so that the color filter layer 4 can also transmit white light, and the brightness can be increased through the white light.

The side of the color filter layer 4 away from the driving backplane 1 may be provided with a light converging layer. The light converging layer includes a plurality of converging lenses 0112 distributed in an array. Each converging lens 0112 is arranged in one-to-one correspondence with each light-emitting device 0111 in a direction perpendicular to the driving backplane 1, and also arranged in one-to-one correspondence with each filter part 0113. The light emitted by any light-emitting device 0111 can pass through its corresponding filter part 0113 and converging lens 0112. The converging lens 0112 can converge the light within a specified range, to improve the brightness of the display panel.

As shown in FIG. 1, the structure of the converging lens 0112 is not particularly limited here, as long as it can achieve the above converging function. For example, the converging lens 0112 may be a spherical cap structure that protrudes in a direction away from the driving backplane 1, and its surface may be surrounded by a plane and a spherical cap.

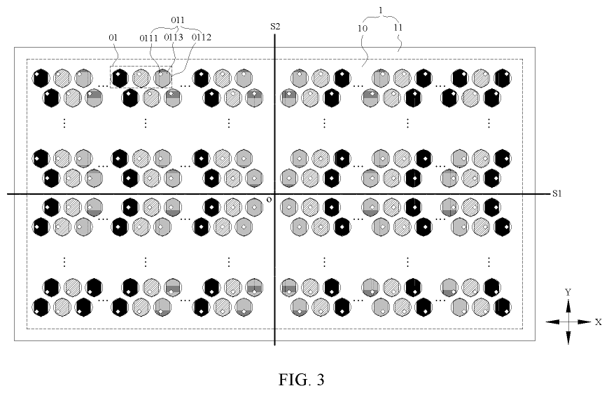

Based on the structure of the display panel above, as shown in FIGS. 1 and 3, a plurality of light-emitting modules 01 can be divided in the display panel. Each light-emitting module 01 is located on one side of the driving backplane 1, and can include a plurality of light-emitting units 011. Each light-emitting unit 011 can be arranged in an array along the row direction and the column direction. Each light-emitting unit 011 may include a light-emitting device 0111 and a corresponding converging lens 0112, as well as a filter part 0113 located between the light-emitting device 0111 and the converging lens 0112. The light-emitting range of the light-emitting unit 011 is jointly limited by the light-emitting device 0111 and the converging lens 0112. The color of the light emitted is defined by the filter part 0113. A light-emitting module 01 can be regarded as a pixel, and each light-emitting unit 011 included in it can be regarded as a sub-pixel.

In some embodiments of the present disclosure, one light-emitting module 01 may include three light-emitting units 011 with different light-emitting colors, such as a red light-emitting unit 011, a green light-emitting unit 011, and a blue light-emitting unit 011.

The solution for improving the uniformity of the display panel of the present disclosure is described in detail below.

As shown in FIG. 2, the pixel region 10 of the driving backplane 1 includes a central region 101 and a plurality of offset regions 102 sequentially surrounding outside the central region 101. The offset regions 102 can extend along a circular trajectory surrounding the central region 101. The circular trajectory can be a circular ring, and it can also be a polygonal ring such as a square ring or other shapes. At the same time, the offset region 102 may be a continuous closed region extending along the annular trajectory, or it may also be an intermittent region distributed at intervals along the annular trajectory. The plurality of offset regions 102 may be distributed in a plurality of concentric rings. At the same time, the central region 101 and each offset region 102 are continuously distributed, the central region 101 is connected to the adjacent offset region 102, and the two adjacent offset regions 102 are connected.

As shown in FIGS. 2 and 3, each light-emitting module 01 can be distributed in the central region 101 and the offset region 102. That is, the light-emitting module 01 is provided within the range of the central region 101 and each offset region 102. Any offset region 102 can be composed of a plurality of sub-regions 1021 distributed around the central region 101, and each light-emitting module 01 is distributed in each sub-region 1021. The sub-region 1021 can be a detection region when detecting the local brightness of the display panel, and the center of the detection region can be distributed annularly with the center of the central region 101 as the center of a circle, to form an offset region 102. The sub-region 1021 may have the same size and shape as the central region 101. The diameter of the sub-region 1021 may be a circular region of 0.2 mm-0.5 mm. In some embodiments of the present disclosure, the pixel region 10 is rectangular, then at least the outermost offset region 102 is a discontinuous annular region formed by a plurality of spaced apart sub-regions 1021, and at least a part of the offset regions 102 are continuous ring regions.

In the same offset region 102, at least two light-emitting modules 01 are distributed along the row direction; at least two light-emitting modules 01 are distributed along the column direction. That is, in any offset region 102, both in the row direction and column direction, there are at least two light-emitting modules 01.

In some embodiments of the present disclosure, the number of light-emitting units 011 in a (k+1)-th offset region 102 in a direction away from the central region is greater than the number of light-emitting units 011 in the k-th offset region 102, k is a positive integer less than n. That is, in two adjacent offset regions 102, the number of light-emitting units 011 in the offset region 102 away from the central region 101 is greater than the number of light-emitting units 011 in the offset region 102 close to the central region 101. k is a positive integer less than n.

In some embodiments of the present disclosure, at least one straight line passing through a center of the central region 101 exists, the number of light-emitting units 011 passing through a (k+1)-th offset region 102 in a direction away from the central region 101 is not less than the number of light-emitting units 011 passing through the k-th offset region 102, k is a positive integer less than n.

In some embodiments of the present disclosure, a gap exists between two adjacent converging lenses 0112.

In two adjacent light-emitting units 011 in the k-th offset region 102 in the direction away from the central region 101, an orthographic projection of the gap between two adjacent converging lenses 0112 on the driving backplane 1 is at least partially located within an orthographic projection of a gap between the two adjacent light-emitting devices 0111 on the driving backplane 1.

In two adjacent light-emitting units 011 in the (k+1)-th offset region 102 in the direction away from the central region 101, an orthographic projection of the gap between two adjacent converging lenses 0112 on the driving backplane 1 is completely located outside the orthographic projection of the gap between the two adjacent light-emitting devices 0111 on the driving backplane 1. k is a positive integer less than n.

The gap between two adjacent light-emitting devices 0111 may refer to the gap between 21 of two adjacent light-emitting devices 0111, or may refer to the region between two adjacent openings 221 of the pixel definition layer 22.

It should be noted that there may be no gap between adjacent converging lenses 0112. The orthogonal projection of the boundary of them two on the driving backplane 1 is located in the orthogonal projection of the gap between two adjacent light emitting devices 0111 on the driving backplane 1.

As shown in FIGS. 2 and 3, the first central axis S1 of the pixel region 10 can pass through at least one sub-region 1021 of each offset region 102, and the second central axis S2 of the pixel region 10 can pass through at least one sub-region 1021 of each offset region 102. The first central axis S1 is the central axis of the pixel region 10 extending along the row direction X. The second central axis S2 is the central axis of the pixel region 10 extending along the column direction Y. The first central axis S1 and the second central axis S2 intersect at the center of the pixel region 10, and the center of the pixel region 10 is the center of the central region 101. At the same time, the distance between the sub-region 1021 and the central region 101 can be defined as the distance (OP) between the center (P) of the sub-region 1021 and the center (O) of the central region 101. The offset region 102 where the center of the sub-region 1021 is located is the offset region 102 wherein the sub-region 1021 is located, and it is not limited that each sub-region 1021 must be completely located in an offset region 102.

As shown in FIGS. 1, 2 and 4, by shifting the center of the light-emitting device 0111 of a light-emitting unit 011 relative to the center of the corresponding converging lens 0112, the angle of the direction in which the luminous intensity of the light emitting unit 011 is maximum relative to the direction perpendicular to the driving backplane 1 is adjusted, i.e., the light-emitting angle of the light emitting unit 011 is adjusted, thereby adjusting the light emitting range. Specifically, in any light-emitting unit 011 in the offset region 102, the center (i) of the orthographic projection of the light-emitting device 0111 on the driving backplane 1 can be located on a side of the center (j) of the orthographic projection of the converging lens 0112 on the driving backplane 1 away from the central region 101. That is, the center of the light-emitting device 0111 of a light-emitting unit 011 is shifted to the outside of the central area 101 relative to the center of the corresponding condenser lens 0112, so that the angle of the direction with the maximum luminous intensity of the light-emitting unit 011 increases outward relative to the direction perpendicular to the driving backplane 1, so that the light-emitting range of the pixel region 10 increases, so as to adapt to the optical path components of the near-eye display device and improve the uniformity of brightness of imaging of the near-eye display device.

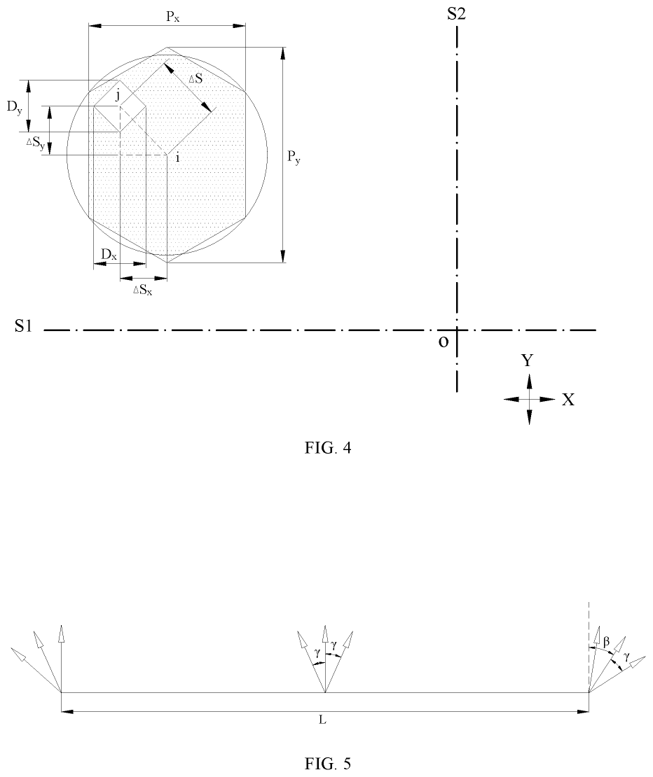

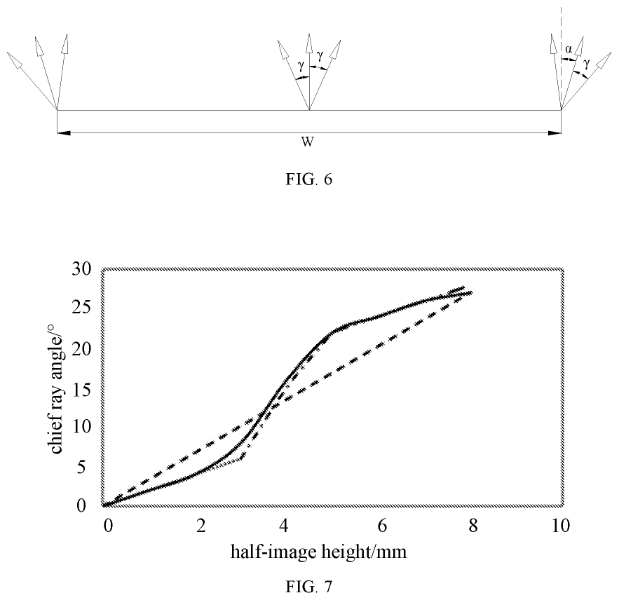

As shown in FIGS. 1 and 4, in any light-emitting unit 011, the distance between the center (i) of the orthographic projection of the light-emitting device 0111 on the driving backplane 1 and the center (j) of the orthographic projection of the converging lens 0112 on the driving backplane 1 can be defined as the offset amount ΔS of the light-emitting unit 011. An extension direction of a connecting line (ij) between the center of the orthographic projection of the light-emitting device 0111 on the driving backplane 1 and the center of the orthographic projection of the converging lens 0112 on the driving backplane 1 is an offset direction of the light-emitting device 0111. As shown in FIGS. 5 and 6, the angle between the direction with the maximum luminous intensity of the light-emitting unit 011 and the direction perpendicular to the driving backplane 1 is the chief ray angle.

As shown in FIGS. 5 and 6, the light-emitting range of any light-emitting unit 011 is the chief ray angle±the designated angle γ. For example, the designated angle γ can be 15°. The designated angle can also be 20° or 10°, etc., which specifically depends on the light-emitting range of the light-emitting device 0111 and the sizes of the filter part 0113 and the converging lens 0112, and is not specifically limited here.

The offset amounts of the light-emitting units 011 in the same offset region 102 are the same, so that the chief ray angles of the light-emitting units 011 in the same offset region 102 are the same, but the offset direction can be radially distributed along the circumferential direction around the central area 101. The offset directions of each light-emitting unit 011 of the same light-emitting module 01 are the same, so as to avoid the different chief ray angles of each light-emitting unit 011 of the same light-emitting module 01 from affecting the picture display.

In the same light-emitting unit 011, the orthographic projection of the light-emitting device 0111 on the driving backplane 1 at least partially coincides with the orthographic projection of the converging lens 0112 on the driving backplane. The two orthographic projections may be an included or completely coincident relationship. That is, the offset amount between the converging lens 0112 and the corresponding light-emitting device 0111 is not greater than the maximum size of the light-emitting device 0111 in the direction parallel to the driving backplane 1, so as to ensure that the light emitted by the light-emitting device 0111 can illuminate the corresponding converging lens 0112.

As shown in FIGS. 1, 5 and 6, the offset amount of the light-emitting unit 011 in the central region 101 is zero. That is, the chief ray angle of the light-emitting unit 011 in the central region 101 is zero, and the direction of its maximum brightness is perpendicular to driving backplane 1. The offset amounts of the light-emitting units 011 in any of the offset regions 102 are greater than the offset amount of the light-emitting unit 011 in the central region 101, and offset amounts of the light-emitting units 011 in different offset regions 102 increase toward a direction away from the central region 101, so that the chief ray angles increase toward the direction away from the central region 101, thereby increasing the luminous range.

The following describes the setting of the offset amount of the light-emitting unit 011 in detail.

As shown in FIG. 4, the offset amount ΔS of any light-emitting unit 011 can be decomposed into a component ΔSₓ along the row direction and a component ΔS_{y} along the column direction. Both the component in the row direction and the component in the column direction can be zero. For example, the component in the row direction and the component in the column direction of the offset amount of the light-emitting unit 011 in the central region 101 are both zero. In addition, if neither the component in the row direction nor the component in the column direction is zero, since the row direction and column direction are perpendicular, according to the Pythagorean theorem, the square of the offset amount is equal to the sum of the squares of the component in the row direction and the component in the column direction.

The components of the offset amounts of the light-emitting units 011 in each of the offset regions 102 in the row direction gradually increase from the central region 101 toward two sides of the central region 101 along the row direction. Meanwhile, components of the offset amounts of the light-emitting units 011 in each of the offset regions 102 in the column direction gradually increase from the central region 101 toward two sides of the central region 101 along the column direction.

A component of the offset amount of the light-emitting unit 011 in the sub-region 1021 through which the first central axis S1 passes in the column direction is zero. That is, the offset direction is the extension direction of the first central axis S1. A component of the offset amount of the light-emitting unit 011 in the sub-region 1021 through which the second central axis S2 passes in the row direction is zero. That is, the offset direction is the extension direction of the second central axis S2. The light-emitting units 011 may be symmetrically distributed about the first central axis S1 and the second central axis S2 respectively.

In some embodiments of the present disclosure, the offset amount of any one of the light-emitting units 011 satisfies the following relational expression:

$$Δ S = {( {( 2 x Δ {S}_{x max} / W )}^{2} + {( 2 y Δ {S}_{y max} / L )}^{2} )}^{\frac{1}{2}} ; \qquad ( 1 )$$

wherein, ΔS is the offset amount of the light-emitting unit 011;
x is a distance in the row direction between a center of the sub-region 1021 where the light-emitting unit 011 is located and a center of the central region 101;
y is the distance in the column direction between the center of the sub-region 1021 where the light-emitting unit 011 is located and the center of the central region 101;
ΔSₓₘₐₓ is a component of an offset amount of the light-emitting unit 011 in the offset region 102 farthest from the central region 101 in the row direction. It should be noted that, in any of the two columns of light-emitting units 011 that are farthest from the central region 101 in the row direction, the offset amounts of different light-emitting units 011 are different, but the components of each light-emitting unit 011 in the row direction are the same, all being ΔSₓₘₐₓ.

ΔS_{ymax} is a component of an offset amount of the light-emitting unit 011 in the offset region 102 farthest from the central region 101 in the column direction. It should be noted that, in any of the two columns of light-emitting units 011 that are farthest from the central region 101 in the column direction, the offset amounts of different light-emitting units 011 are different, but the components of each light-emitting unit 011 in the column direction are the same, all being ΔS_{ymax}.

W is a length of the pixel region 10 in the row direction, and L is the length of the pixel region 10 in the column direction. For example, the shape of the pixel region 10 is a rectangle, W is the width, L is the length, L:W is the aspect ratio, which can be 16:9 or 4:3, etc., or it can also be 1:1, which is not specially limited herein. It should be noted that W and L can be characterized by units such as cm and mm, or characterized by the number of rows and columns of the light-emitting unit 011.

In addition, the inventor found that the optical path components of at least some of near-eye display devices such as virtual reality devices and augmented reality devices have non-linear requirements for the chief ray angle of the light emitting unit 011 of the display panel. Therefore, in order to match the chief ray angle of the light-emitting unit 011 with the optical path component, the chief ray angle of each light-emitting unit 011 can be nonlinearly increased toward a direction away from the central region 101. In other embodiments of the present disclosure, each of the offset regions 102 may be divided into m sections sequentially distributed toward a direction away from the central region 101, m is a positive integer. Each of the sections includes a plurality of the offset regions 102. That is, m is smaller than n. The number of offset regions 102 in different sections may be the same or different, and is not specifically limited here.

In any of the sections, the offset amounts of the light-emitting units 011 in each of the offset regions 102 linearly increase with increase of a distance between the offset region 102 and the central region 101, and a growth rate of the offset amount may be defined as a growth rate of the section. The distance between the offset region 102 and the central region 101 may be the distance between the center of the offset region 102 and the central region 101. The growth rate of the offset amount can be the ratio of the maximum offset amount to the minimum offset amount in the section.

The growth rates of different sections can be different, so that the offset amounts of respective section increase nonlinearly toward the direction away from the central region 101, and accordingly, the chief ray angles also increase nonlinearly, which more matches with needs of the optical path components.

Furthermore, the sections may include a first section, a second section and a third section sequentially distributed toward a direction away from the central region 101. A growth rate of the second section may be greater than that of the first section, and a growth rate of the third section may be less than that of the first section.

During specific implementation, a plurality of sections can be divided according to the distance between the center of the pixel region 10 and the offset region 102, and the offset required for the outermost offset region 102 of each section is determined through optical simulation respectively. Then, based on these offset amounts, the offset amount required for each offset region 102 is calculated according to the distance between the center of the pixel region 10 and the offset region 102, to achieve piecewise linear gradient offset. Correspondingly, the chief ray angle can increase non-linearly as the half-image height of the pixel region 10 increases. Referring to FIG. 7, the dashed line of FIG. 7 shows the actual trend of the nonlinear increase in the chief ray angle of a plurality of sections, and the solid line shows the ideal trend of the chief ray angle derived from optical simulation. It can be seen that the actual trend is roughly consistent with the ideal trend.

As shown in FIGS. 5 and 6, in some embodiments of the present disclosure, in the same offset region 102, the chief ray angle of the light-emitting unit 011 in the sub-region 1021 passing through the first central axis S1 is the first included angle; the chief ray angle of the light-emitting unit 011 in the sub-region 1021 passing through the second central axis S2 is the second included angle. The first included angle and the second included angle satisfy the following relational expression:

$$α = β W / L ; \qquad ( 2 )$$

wherein, α is the first included angle, β is the second included angle, and the meanings of W and L are the same as W and L in the relational expression (1).

Through the above relational expression (2), the relationship between the first included angle and the second included angle can be established based on W and L. If W:L≠1:1, then α≠β, so that the luminous range of the edge of the pixel region 10 in the row direction and the edge of the pixel region 10 in the column direction matches the shape of the pixel region 10. For example, W:L=9:16, then α=9β/16, and the first included angle α is smaller than the second included angle β.

In addition, as shown in FIGS. 1 and 4, the center of the orthographic projection of the filter part 0113 on the driving backplane 1 may coincide with the center of the orthographic projection of the corresponding converging lens 0112 on the driving backplane 1. That is, in any light-emitting unit 011, the filter part 0113 does not shift relative to the converging lens 0112, but the light-emitting device 0111 shifts relative to the filter part 0113 and the converging lens 0112. When the filter part 0113 does not shift relative to the converging lens 0112, the light emitted from the same filter part 0113 can be prevented from entering two adjacent converging lenses 0112 at the same time, thereby preventing cross-color between adjacent light-emitting units 011.

As shown in FIGS. 1 and 4, in some embodiments of the present disclosure, a component of the offset amount of any of the light-emitting units in the row direction may satisfy the following relational expression:

$$0 \leq Δ {S}_{x} \leq ( {P}_{x} - {D}_{x} ) / 2 ; \qquad ( 3 )$$

wherein, ΔSₓ is the component of the offset amount of any of the light-emitting units 011 in the row direction;
Pₓ is a length of a filter part 0113 of the light-emitting unit 011 corresponding to ΔSₓ in the row direction;
Dₓ is a length of the light-emitting device 0111 of the light-emitting unit 011 corresponding to ΔSₓ in the row direction.

Through the above-mentioned relational expression (3), the component of the offset amount of the light-emitting unit 011 in the row direction can be limited, which is helpful to prevent the offset amount from being too large and causing the light emitted by the light-emitting device 0111 to be incident in the filter part 0113 of the adjacent light-emitting unit 011, which is helpful to avoid cross-color occurrence in adjacent light-emitting units 011 and ensure the uniformity of chromaticity.

As shown in FIG. 4, in some embodiments of the present disclosure, a component of the offset amount of any of the light-emitting units 011 in the row direction satisfies the following relational expression:

$$0 \leq Δ {S}_{y} \leq ( {P}_{y} - {D}_{y} ) / 2 ; \qquad ( 4 )$$

wherein, ΔS_{y} is the component of the offset amount of any of the light-emitting units 011 in the column direction;
P_{y} is a length of a filter part 0113 of the light-emitting unit 011 corresponding to ΔS_{y} in the column direction;
D_{y} is a length of the light-emitting device 0111 of the light-emitting unit 011 corresponding to ΔS_{y} in the column direction.

Through the above-mentioned relational expression (4), the component of the offset amount of the light-emitting unit 011 in the column direction can be limited, which is helpful to prevent the offset amount from being too large and causing the light emitted by the light-emitting device 0111 to be incident in the filter part 0113 of the adjacent light-emitting unit 011, which is helpful to avoid cross-color occurrence in adjacent light-emitting units 011 and ensure the uniformity of chromaticity.

In some embodiments of the present disclosure, the above-mentioned ΔSₓ and ΔS_{y} can be defined at the same time, that is, defined using the relational expression (3) and the relational expression (4) at the same time, thus defining the two components of offset amounts ΔS of the light-emitting unit 011, to avoid cross-color to the greatest extent.

In some embodiments of the present disclosure, in order to achieve the offset of the filter part 0113 relative to its corresponding light-emitting device 0111, the width of the filter part can be increased in a direction away from the central region 101. Specifically, a width of the filter part 0113 in the (k+1)-th offset region 102 in a direction away from the central region 101 is greater than a width of the filter part 0113 with an identical color in the k-th offset region 102 as in the (k+1)-th offset region 102, and k is a positive integer less than n. By increasing the width of the filter part 0113, the center of the filter part 0113 can be correspondingly shifted toward the direction away from the central region 101, thereby achieving relative shift between the light-emitting device 0111 and the filter part 0113.

The present disclosure also provides a method for manufacturing a display panel. The display panel is the display panel in any of the above embodiments, and its specific structure will not be described in detail here. Correspondingly, the manufacturing method may include steps S110 to S130:
step S110, forming a driving backplane 1 having a pixel region 10, wherein the pixel region 10 includes a central region and n offset regions 102 sequentially surrounding outside the central region, n is a positive integer;
step S120, forming a plurality of light-emitting devices 0111 distributed in an array in the central region and the offset regions 102 on a side of the driving backplane 1;
step S130, forming converging lenses 0112 corresponding to the light emitting devices 0111 one by one on a side of the light-emitting device 0111 away from the driving backplane 1, wherein the converging lens 0112 is used for converging light emitted by the light-emitting devices 0111 within a specified angle;
wherein each of the light-emitting units 011 is divided into a plurality of light-emitting modules 01, wherein one of the light-emitting modules 01 includes a plurality of light-emitting units 011, and one of the light-emitting units 011 includes a light-emitting device 0111 and a corresponding converging lens 0112;
wherein in any of the light-emitting units 011 in the offset region 102, a center of an orthographic projection of the light-emitting device 0111 on the driving backplane 1 is located on a side of a center of an orthographic projection of the converging lens 0112 on the driving backplane 1 away from the central region, and a distance between the center of the orthographic projection of the light-emitting device 0111 on the driving backplane 1 and the center of the orthographic projection of the converging lens 0112 on the driving backplane 1 is an offset amount of the light-emitting unit 011; and an extension direction of a connecting line between the center of the orthographic projection of the light-emitting device 0111 on the driving backplane 1 and the center of the orthographic projection of the converging lens 0112 on the driving backplane 1 is an offset direction of the light-emitting device 0111;
offset amounts of the light-emitting units 011 in an identical offset region 102 are identical; and offset directions of the light-emitting units 011 in an identical light-emitting module 01 are identical; and
an offset amount of the light-emitting unit 011 in the central region is zero; offset amounts of the light-emitting units 011 in any of the offset regions 102 are greater than the offset amount of the light-emitting unit 011 in the central region, and offset amounts of the light-emitting units 011 in each of the offset regions 102 increase toward a direction away from the central region.

It should be noted that although the various steps of the manufacturing method in the present disclosure are described in a specific order in the drawings, this does not require or imply that these steps must be performed in this specific order, or that all of the steps shown must be performed to achieve the desired results. Additionally or alternatively, certain steps may be omitted, multiple steps may be combined into one step for execution, and/or one step may be decomposed into multiple steps for execution, etc.

The present disclosure also provides a display apparatus, which may include a display panel. For the structure of the display panel, reference may be made to the above embodiments of the display panel, which will not be described in detail here. Since the display apparatus adopts the display panel of the present disclosure, the beneficial effects of the display apparatus can also be referred to the beneficial effects of the display panel.

The display apparatus of the present disclosure can be used in near-eye display devices such as virtual reality devices and augmented reality devices, and is used to emit light to the optical path components of the near-eye display device, in order to present pictures. The detailed principle and structure of the near-eye display device are not particularly limited here, as long as image display can be achieved. Due to the use of the display apparatus of the present disclosure, the light emitting range of the display apparatus can be matched with the optical path component, thereby improving the uniformity of brightness of the pictures of the near-eye display device.

Other embodiments of the present disclosure will readily come to the mind of those skilled in the art after considering the specification and practicing the disclosure disclosed herein. This application is intended to cover any variations, uses, or adaptations of the present disclosure that follow the general principles of the present disclosure and include commonly known or customary technical means in the art that are not disclosed herein. The specification and embodiments are to be considered exemplary only, and the true scope and spirit of the present disclosure is indicated by the appended claims.

1. A display panel, comprising:
a driving backplane, having a pixel region, wherein the pixel region comprises a central region and n offset regions sequentially surrounding outside the central region, n is a positive integer;
a plurality of light-emitting modules, provided on a side of the driving backplane and distributed in the central region and the offset regions, wherein one of the light-emitting modules comprises a plurality of light-emitting units, and one of the light-emitting units comprises a light-emitting device and a converging lens distributed along a direction away from the driving backplane;
in any of the light-emitting units in the offset region, a center of an orthographic projection of the light-emitting device on the driving backplane is located on a side of a center of an orthographic projection of the converging lens on the driving backplane away from the central region, and a distance between the center of the orthographic projection of the light-emitting device on the driving backplane and the center of the orthographic projection of the converging lens on the driving backplane is an offset amount of the light-emitting unit; and an extension direction of a connecting line between the center of the orthographic projection of the light-emitting device on the driving backplane and the center of the orthographic projection of the converging lens on the driving backplane is an offset direction of the light-emitting device;
offset amounts of the light-emitting units in an identical offset region are identical; and offset directions of the light-emitting units in an identical light-emitting module are identical; and
an offset amount of the light-emitting unit in the central region is zero; offset amounts of the light-emitting units in any of the offset regions are greater than the offset amount of the light-emitting unit in the central region, and offset amounts of the light-emitting units in each of the offset regions increase toward a direction away from the central region.

2. The display panel according to claim 1, wherein the light-emitting units are distributed in an array along a row direction and a column direction;
components of the offset amounts of the light-emitting units in each of the offset regions in the row direction gradually increase toward two sides of the central region along the row direction;
components of the offset amounts of the light-emitting units in each of the offset regions in the column direction gradually increase toward two sides of the central region along the column direction.

3. The display panel according to claim 2, wherein the offset region comprises a plurality of sub-regions distributed around the central region; the light-emitting modules are distributed in each of the sub-regions;
in an identical offset region, a first central axis of the pixel region passes through at least one of the sub-regions, and a second central axis of the pixel region passes through at least one of the sub-regions; the first central axis is a central axis extending along the row direction, and the second central axis is a central axis extending along the column direction;
a component of the offset amount of the light-emitting unit in the sub-region through which the first central axis passes in the column direction is zero; and a component of the offset amount of the light-emitting unit in the sub-region through which the second central axis passes in the row direction is zero.

4. The display panel according to claim 2, wherein the light-emitting unit further comprises:
a filter part, provided between the light-emitting device and the converging lens;
colors of the filter parts of at least two different light-emitting units of the identical light-emitting module are different.

5. The display panel according to claim 4, wherein a center of an orthographic projection of the filter part on the driving backplane coincides with the center of the orthographic projection of the converging lens on the driving backplane.

6. The display panel according to claim 5, wherein a component of the offset amount of any of the light-emitting units in the row direction satisfies the following relational expression:
$$0 \leq Δ {S}_{x} \leq ( {P}_{x} - {D}_{x} ) / 2 ;$$
wherein, ΔSₓ is the component of the offset amount of any of the light-emitting units in the row direction;
Pₓ is a length of a filter part of the light-emitting unit corresponding to ΔSₓ in the row direction;
Dₓ is a length of the light-emitting device of the light-emitting unit corresponding to ΔSₓ in the row direction.

7. The display panel according to claim 5, wherein a component of the offset amount of any of the light-emitting units in the row direction satisfies the following relational expression:
$$0 \leq Δ {S}_{y} \leq ( {P}_{y} - {D}_{y} ) / 2 ;$$
wherein, ΔS_{y} is the component of the offset amount of any of the light-emitting units in the column direction;
P_{y} is a length of a filter part of the light-emitting unit corresponding to ΔS_{y} in the column direction;
D_{y} is a length of the light-emitting device of the light-emitting unit corresponding to ΔS_{y} in the column direction.

8. The display panel according to claim 3, wherein the offset amount of any one of the light-emitting units satisfies the following relational expression:
$$Δ S = {( {( 2 x Δ {S}_{x max} / W )}^{2} + {( 2 y Δ {S}_{y max} / L )}^{2} )}^{\frac{1}{2}} ;$$
wherein, ΔS is the offset amount of the light-emitting unit;
x is a distance in the row direction between a center of the sub-region where the light-emitting unit is located and a center of the central region;
y is the distance in the column direction between the center of the sub-region where the light-emitting unit is located and the center of the central region;
ΔSₓₘₐₓ is a component of an offset amount of the light-emitting unit in the offset region farthest from the central region in the row direction;
ΔS_{ymax} is a component of an offset amount of the light-emitting unit in the offset region farthest from the central region in the column direction;
W is a length of the pixel region in the row direction;
L is the length of the pixel region in the column direction.

9. The display panel according to claim 3, wherein each of the offset regions is divided into m sections sequentially distributed toward a direction away from the central region, and each of the sections comprises a plurality of the offset regions; m is a positive integer;
in any of the sections, the offset amounts of the light-emitting units in each of the offset regions linearly increase with increase of a distance between the offset region and the central region, and a growth rate of the offset amount is that of the section;
growth rates of at least two of the sections are different.

10. The display panel according to claim 9, wherein the sections comprise a first section, a second section and a third section sequentially distributed toward a direction away from the central region;
a growth rate of the second section is greater than that of the first section, and a growth rate of the third section is less than that of the first section.

11. The display panel according to claim 3, wherein in an identical offset region, an included angle between a direction with a maximum luminous intensity of the light-emitting unit in the sub-region passing through the first central axis and a direction perpendicular to the driving backplane is a first included angle; and an included angle between a direction with the maximum luminous intensity of the light-emitting unit in the sub-region passing through the second central axis and a direction perpendicular to the driving backplane is a second included angle;
the first included angle and the second included angle satisfy the following relational expression:
$$α = β W / L ;$$
wherein, α is the first included angle, and β is the second included angle.

12. The display panel according to claim 1, wherein the converging lens is a spherical cap structure protruding away from the driving backplane.

13. The display panel of claim 4, further comprising:
an encapsulation layer, covering each of the light-emitting modules; wherein the filter part is provided on a side of the encapsulation layer away from the driving backplane.

14. The display panel according to claim 1, wherein in an identical offset region, at least two of the light-emitting modules are distributed along the row direction; and at least two of the light-emitting modules are distributed along the column direction.

15. The display panel according to claim 1, wherein the number of light-emitting units in a (k+1)-th offset region in a direction away from the central region is greater than the number of light-emitting units in the k-th offset region, k is a positive integer less than n.

16. The display panel according to claim 1, wherein at least one straight line passing through a center of the central region exists, the number of light-emitting units passing through a (k+1)-th offset region in a direction away from the central region is not less than the number of light-emitting units passing through the k-th offset region, k is a positive integer less than n.

17. The display panel according to claim 1, wherein in an identical light-emitting unit, the orthographic projection of the light-emitting device on the driving backplane at least partially coincides with the orthographic projection of the converging lens on the driving backplane.

18. The display panel according to claim 1, wherein a gap exists between two adjacent converging lenses;
in two adjacent light-emitting units in the k-th offset region in the direction away from the central region, an orthographic projection of the gap between two adjacent converging lenses on the driving backplane is at least partially located within an orthographic projection of a gap between the two adjacent light-emitting devices on the driving backplane;
in two adjacent light-emitting units in the (k+1)-th offset region in the direction away from the central region, an orthographic projection of the gap between two adjacent converging lenses on the driving backplane is completely located outside the orthographic projection of the gap between the two adjacent light-emitting devices on the driving backplane;
k is a positive integer less than n.

19. The display panel according to claim 4, wherein a width of the filter part in the (k+1)-th offset region in a direction away from the central region is greater than a width of the filter part with an identical color in the k-th offset region as in the (k+1)-th offset region;
k is a positive integer less than n.

20. A method of manufacturing a display panel, comprising:
forming a driving backplane having a pixel region, wherein the pixel region comprises a central region and n offset regions sequentially surrounding outside the central region, n is a positive integer;
forming a plurality of light-emitting devices distributed in an array in the central region and the offset regions on a side of the driving backplane;
forming converging lenses corresponding to the light emitting devices one by one on a side of the light-emitting device away from the driving backplane, wherein the converging lens is used for converging light emitted by the light-emitting devices within a specified angle;
dividing each of the light-emitting units into a plurality of light-emitting modules, wherein one of the light-emitting modules comprises a plurality of light-emitting units, and one of the light-emitting units comprises a light-emitting device and a corresponding converging lens;
wherein in any of the light-emitting units in the offset region, a center of an orthographic projection of the light-emitting device on the driving backplane is located on a side of a center of an orthographic projection of the converging lens on the driving backplane away from the central region, and a distance between the center of the orthographic projection of the light-emitting device on the driving backplane and the center of the orthographic projection of the converging lens on the driving backplane is an offset amount of the light-emitting unit; and an extension direction of a connecting line between the center of the orthographic projection of the light-emitting device on the driving backplane and the center of the orthographic projection of the converging lens on the driving backplane is an offset direction of the light-emitting device;
offset amounts of the light-emitting units in an identical offset region are identical; and offset directions of the light-emitting units in an identical light-emitting module are identical; and
an offset amount of the light-emitting unit in the central region is zero; offset amounts of the light-emitting units in any of the offset regions are greater than the offset amount of the light-emitting unit in the central region, and offset amounts of the light-emitting units in each of the offset regions increase toward a direction away from the central region.

21. A display apparatus, comprising a display panel, wherein the display panel comprises:
a driving backplane, having a pixel region, wherein the pixel region comprises a central region and n offset regions sequentially surrounding outside the central region, n is a positive integer;
a plurality of light-emitting modules, provided on a side of the driving backplane and distributed in the central region and the offset regions, wherein one of the light-emitting modules comprises a plurality of light-emitting units, and one of the light-emitting units comprises a light-emitting device and a converging lens distributed along a direction away from the driving backplane;
in any of the light-emitting units in the offset region, a center of an orthographic projection of the light-emitting device on the driving backplane is located on a side of a center of an orthographic projection of the converging lens on the driving backplane away from the central region, and a distance between the center of the orthographic projection of the light-emitting device on the driving backplane and the center of the orthographic projection of the converging lens on the driving backplane is an offset amount of the light-emitting unit; and an extension direction of a connecting line between the center of the orthographic projection of the light-emitting device on the driving backplane and the center of the orthographic projection of the converging lens on the driving backplane is an offset direction of the light-emitting device;
offset amounts of the light-emitting units in an identical offset region are identical; and offset directions of the light-emitting units in an identical light-emitting module are identical; and
an offset amount of the light-emitting unit in the central region is zero; offset amounts of the light-emitting units in any of the offset regions are greater than the offset amount of the light-emitting unit in the central region, and offset amounts of the light-emitting units in each of the offset regions increase toward a direction away from the central region.
